(19) United States
(12) Patent Application Publication
(10) Pub. No.: US 2025/0160110 A1
(43) Pub. Date: May 15, 2025

(54) LIGHT-EMITTING ELEMENT, DISPLAY DEVICE, AND METHOD FOR MANUFACTURING LIGHT-EMITTING ELEMENT

(71) Applicant: Sharp Display Technology Corporation, Kameyama City. Mie (JP)

(72) Inventors: MASAYA UEDA, Sakai City, Osaka (JP); Satoru YAMAMOTO, Sakai City, Osaka (JP); Masaki YAMAMOTO, Sakai City, Osaka (JP); Tatsuya RYOHWA, Sakai City, Osaka (JP); Makoto IZUMI, Sakai City, Osaka (JP)

(21) Appl. No.: 18/833,624

(22) PCT Filed: Mar. 29, 2022
(86) PCT No.: PCT/JP2022/015300

§ 371 Date: Jul. 26, 2024

(51) Int. Cl. H10K 50/115; H10K 101/00

(52) U.S. Cl. CPC H10K 50/115; H10K 2101/80

(57) ABSTRACT

A light-emitting element includes a first electrode, a second electrode, and a light-emitting layer located between the first electrode and the second electrode, in which the light-emitting layer includes a first nanoparticle group including a first nanoparticle and spreading in a layer shape, a first quantum dots located between the first electrode and the first nanoparticle group and a second quantum dots located between the second electrode and the first nanoparticle group.

### TECHNICAL FIELD

The disclosure relates to a light-emitting element, a display device, and a manufacturing method for a light-emitting element.

### BACKGROUND ART

PTLs 1 to 3 disclose a light-emitting element provided with a light-emitting layer including quantum dots.

### CITATION LIST

### Patent Literature

PTL 1: JP 2007-095685 A (published on Apr. 12, 2007)
PTL 2: US 2019/0280232 A1 (published on Sep. 12, 2019)
PTL 3: WO2020/208810 A1 (published on Oct. 15, 2020)

### SUMMARY

### Technical Problem

There is a demand for improving luminous efficiency of a light-emitting element including quantum dots.

### Solution to Problem

A light-emitting element according to an aspect of the disclosure includes a first electrode, a second electrode, and a light-emitting layer located between the first electrode and the second electrode, in which the light-emitting layer includes a first nanoparticle group including first nanoparticles and spreading in a layered manner, a first quantum dot located between the first electrode and the first nanoparticle group and differing from each of the first nanoparticles in at least one of a constituent element, a composition, or a particle diameter, and a second quantum dot located between the second electrode and the first nanoparticle group and differing from each of the first nanoparticles in at least one of a constituent element, a composition, or a particle diameter.

### Advantageous Effects of Disclosure

According to an aspect of the disclosure, luminous efficiency of a light-emitting element including quantum dots improves.

### BRIEF DESCRIPTION OF DRAWINGS

FIG. 1 is a cross-sectional view illustrating a configuration example of a light-emitting element according to the present embodiment.

FIG. 2 is a cross-sectional view illustrating a configuration example of the light-emitting element according to the present embodiment.

FIG. 3 is a cross-sectional view illustrating a configuration example of the light-emitting element according to the present embodiment.

FIG. 4 is a cross-sectional view illustrating a configuration example of the light-emitting element according to the present embodiment.

FIG. 5 is a cross-sectional view illustrating a configuration example of a nanoparticle.

FIG. 6 is a cross-sectional view illustrating a configuration example of a periphery of the nanoparticle.

FIG. 7 is a cross-sectional view illustrating a configuration example of a nanoparticle group.

FIG. 8 is a cross-sectional view illustrating a configuration example of a quantum dot.

FIG. 9 is a cross-sectional view illustrating a configuration example of the light-emitting element according to the present embodiment.

FIG. 10 is a cross-sectional view illustrating a configuration example of the light-emitting element according to the present embodiment.

FIG. 11 is a cross-sectional view illustrating a configuration example of the light-emitting element according to the present embodiment.

FIG. 12 is a cross-sectional view illustrating a configuration example of the light-emitting element according to the present embodiment.

FIG. 13 is a cross-sectional view illustrating a configuration example of the light-emitting element according to the present embodiment.

FIG. 14 is a cross-sectional view illustrating a configuration example of the light-emitting element according to the present embodiment.

FIG. 15 is a flowchart illustrating an example of a manufacturing method for the light-emitting element according to the present embodiment.

FIG. 16 is a flowchart illustrating an example of a manufacturing method for the light-emitting element according to the present embodiment.

FIG. 17 is a schematic view illustrating a configuration example of a display device including the light-emitting element according to the present embodiment.

### DESCRIPTION OF EMBODIMENTS

### Light-Emitting Element

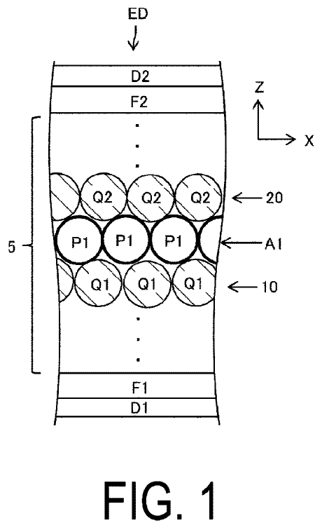

FIG. 1 is a cross-sectional view illustrating a configuration example of a light-emitting element according to the present embodiment. As illustrated in FIG. 1, a light-emitting element 1 of the present embodiment includes a first electrode D1, a second electrode D2, and a light-emitting layer 5 located between the first electrode D1 and the second electrode D2, in which the light-emitting layer 5 includes a first nanoparticle group A1 including first nanoparticles P1 and spreading in a layered manner, first quantum dots Q1 located between the first electrode D1 and the first nanoparticle group A1 and differing from the first nanoparticles P1 in at least one of a constituent element, a composition, or a particle diameter, and second quantum dots Q2 located between the second electrode D2 and the first nanoparticle group A1 and differing from the first nanoparticles P1 in at least one of a constituent element, a composition, or a particle diameter. “Differing in composition” means that the constituent element is the same but a constituent proportion (composition ratio) thereof is different.

The quantum dot in the disclosure is a particle capable of emitting light and having a maximum width of 100 nm or less. The shape of the quantum dot, that is, the shape of the particle is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof. Typically, examples include a semiconductor. The semiconductor as used herein means a material having a certain band gap and capable of emitting light, and includes at least the following materials. That is, the semiconductor includes, for example, at least one type selected from the group consisting of a group II-VI compound, a group III-V compound, and a chalcogenide and a perovskite compound. Note that, the group II-VI compound refers to a compound including a group II element and a group VI element, and the group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element. Note that, the numbering of groups of an element by using Roman numerals is numbering based on the old International Union of Pure and Applied Chemistry (IUPAC) system or old Chemical Abstracts Service (CAS) system, and the numbering of groups of an element by using Arabic numerals is numbering based on the current IUPAC system.

Examples of the group II-VI compound include at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

Examples of the group III-V compound include at least one kind selected from the group consisting of GaAs, GaP, InN, InAs, InP, and InSb.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃. Examples of the constituent element X include at least one kind selected from the group consisting of Cl, Br and I.

Note that, “nanoparticle” means a particle having a nano size (particle diameter of less than 1000 nm). The shape of the particle may be the same as the shape of the particle described in the description of the “shape of the particle” of the quantum dot. The first nanoparticle P1 may be a light transmissive body. The first and second quantum dots Q1 and Q2 may emit electroluminescence with light-emitting wavelengths in the visible light region.

One of the first electrode D1 and the second electrode D2 is an anode, and the other is a cathode. When a voltage is applied between the anode and the cathode, holes from the anode and electrons from the cathode are recombined in the light-emitting layer 5 including the first and second quantum dots Q1 and Q2, and excitons generated by the recombination return to a ground state to generate light. The light generated in the light-emitting layer 5 may be blue light, green light or red light.

By providing the first nanoparticle group A1, the first nanoparticle group A1 functions as a spacer, and a distance between the first and second quantum dots Q1 and Q2 in a Z direction can be maintained where the Z direction is a thickness direction of the light-emitting layer 5. As a result, the luminous efficiency of the light-emitting element 1 is improved. This is because when a distance between the quantum dots (for example, the distance in the Z direction) is small, excitation energy is easily transferred between the quantum dots, which may cause a decrease in luminous efficiency. For example, it is known that when the distance between the quantum dots is small, the excitation energy is transferred by fluorescence resonance energy transfer (FRET). The FRET may transfer the exciton to another quantum dot or to a non-emitting center. The latter is a cause of deactivation of the exciton, that is, a cause of reduction in luminous efficiency of the quantum dots. In addition, for example, when the distance between the quantum dots is small, the density of the quantum dots (the number of quantum dots per volume) is great. When the density of the quantum dots is great, the light emission of the quantum dot may be absorbed by another quantum dot or the non-emitting center. The latter causes a decrease in the luminous efficiency of the quantum dot. There is also an advantage that the first nanoparticle group A1 functions as a protection layer of the first quantum dots Q1, and the first quantum dots Q1 are less likely to be damaged in a step after the formation of the first quantum dots. The first and second quantum dots Q1 and Q2 may be made of the same material, may have an equivalent particle diameter, and may perform light emission of the same color. Here, “light emission of the same color” means light emission by the quantum dots having a composition and a particle diameter which can be used in a range regarded as the same color in a light-emitting element. The same color is the same color in the sense that the colors belong to any of a plurality of primary colors constituting a display image such as red, green, and blue. For this reason, the same color only requires that the colors be substantially the same within a range visible to human eyes, and it is not required that the peak of the wavelength of light be completely the same in a strict sense. For example, when two peaks are detected in a light-emitting wavelength spectrum of two types of quantum dots and the respective peak wavelengths are within the range of each of wavelengths of 400 nm or more and 500 nm or less representing blue, more than 500 nm and 600 nm or less representing green, and more than 600 nm and 780 nm or less representing red, it is assumed that the quantum dots perform light emission of the same color. Naturally, it is assumed that the quantum dots are also the same in a case where two peaks are not detected in the light-emitting wavelength spectrum of the plurality of quantum dots.

The equivalent particle diameter means a case where only one peak is observed when the number of classes from the maximum to the minimum of data is 6 in a histogram with the particle diameter as a horizontal axis in which particles adjacent to each other as much as possible are extracted and the particle diameters of 30 particles in total are measured in a cross-sectional observation image of the light-emitting layer 5 in a layer thickness direction (Z direction). Further, “differing in a particle diameter” means that two or more peaks are observed when a histogram is prepared in the same manner. When particle diameters of particles at distant locations are to be measured, comparison should be made using substantially the same number of samples at different locations. For a particle diameter when the cross-section is not a circle, a diameter of a circle having an area corresponding to an area of the particle in the cross-sectional observation image can be used as the particle diameter.

The first nanoparticle P1 may include an insulating material. At least a part (in particular, a core which is the central portion) or the entirety of the first nanoparticle P1 may be made of a light-transmitting insulating material such as SiO₂, Al₂O₃, or diamond. The first nanoparticle P1 may have insulating properties (electrical conductivity is 1/10 or less of that of the first quantum dot Q1) or may be non-emitting (luminous efficiency is 1/10 or less of that of the first quantum dot Q1).

The particle diameter of the second quantum dot Q2 may be equivalent to the particle diameter of the first quantum dot Q1. In this case, the first nanoparticle group A1 is easily formed in a layered manner. The particle diameter of the first nanoparticle P1 may be equivalent to the particle diameter of the first quantum dot Q1. In this case, since the first nanoparticle P1 is likely to be located at the position of closest packing, the arrangement of the first nanoparticle group A1 can be controlled with higher accuracy. Thus, the distance between the first quantum dot Q1 and the second quantum dot Q2 can be controlled with higher accuracy.

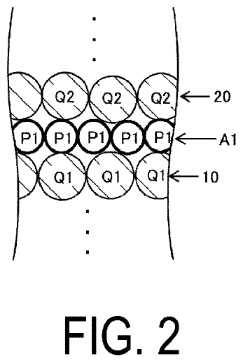

FIG. 2 is a cross-sectional view illustrating a configuration example of the light-emitting element according to the present embodiment. As illustrated in FIG. 2, the particle diameter of the first nanoparticle P1 may be smaller than the particle diameter of the first quantum dot Q1, and in this case, the first nanoparticles P1 are less likely to be missing as the spacer. The band gap of the first nanoparticle P1 may be greater than the band gap of the first quantum dot Q1. In this case, light emission recombination is less likely to occur in the first nanoparticle P1.

The band gap of the first nanoparticle P1 may be 3.1 [eV] or more (light-emitting wavelength 400 nm or less) or 1.8 [eV] or less (light-emitting wavelength 700 nm or more). In this case, since the first nanoparticle P1 does not emit visible light, color mixing (broadening of light-emitting characteristics of the light-emitting element ED) can be prevented.

The light-emitting layer 5 may include a first quantum dot group 10 including the first quantum dots Q1 and spreading in a layered manner. In this case, a greater amount of the first quantum dots Q1 can be included in the light-emitting layer 5. The light-emitting layer 5 may include the first quantum dot group 20 including the second quantum dots Q2 and spreading in a layered manner. In this case, a greater amount of the second quantum dots Q2 can be included in the light-emitting layer 5.

The first electrode D1 may be one of an anode and a cathode, and the second electrode D2 may be the other. A first charge function layer F1 (for example, one of an electron transport layer and a hole transport layer) may be provided between the first electrode D1 and the first quantum dot group 10, and a second charge function layer F2 (for example, the other of the electron transport layer and the hole transport layer) may be provided between a second quantum dot group 20 and the second electrode D2.

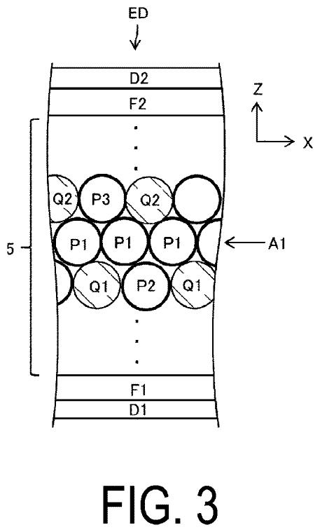

FIG. 3 is a cross-sectional view illustrating a configuration example of the light-emitting element according to the present embodiment. As illustrated in FIG. 3, the light-emitting layer 5 may include second nanoparticles P2 located between the first electrode D1 and the first nanoparticle group A1. The second nanoparticle P2 and the first quantum dot Q1 may be adjacent to each other in a direction (X direction) orthogonal to the layer thickness direction of the light-emitting layer 5. In this case, the distance between adjacent ones of the first quantum dots Q1 in the X direction can be maintained, and the luminous efficiency of the light-emitting element 1 is improved. The second nanoparticle P2 may be a semiconductor crystal having a greater band gap than the first quantum dot Q1. In this case, light emission recombination is less likely to occur in the second nanoparticle P2.

The light-emitting layer 5 may include third nanoparticles P3 located between the second electrode D2 and the first nanoparticle group A1. The third nanoparticle P3 and the second quantum dot Q2 may be adjacent to each other in the direction (X direction) orthogonal to the layer thickness direction of the light-emitting layer 5. Luminous efficiency of the light-emitting element 1 is improved for the same reason as the second nanoparticle. The third nanoparticle P3 may be a semiconductor crystal having a band gap greater than the second quantum dot Q2. Light emission recombination is less likely to occur in the third nanoparticle P3.

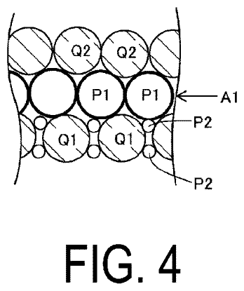

FIG. 4 is a cross-sectional view illustrating a configuration example of the light-emitting element according to the present embodiment. As illustrated in FIG. 4, the particle diameter of the second nanoparticle P2 may be smaller than the particle diameter of the first quantum dot Q1, and a plurality of the second nanoparticles P2 may be disposed in a gap between adjacent ones of the first quantum dots Q1. Since the distance is controlled by the second nanoparticle P2 having a smaller diameter, more detailed control is possible. In addition, since the distance is controlled by the plurality of second nanoparticles P2, missing of the second nanoparticles P2 is less likely to occur.

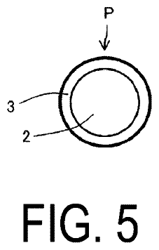

FIG. 5 is a cross-sectional view illustrating a configuration example of a nanoparticle. The first nanoparticle P1, the second nanoparticle P2, the third nanoparticle P3, and the like are collectively referred to as a nanoparticle P. The nanoparticle P may include at least one of an n-type conductive material or a p-type conductive material, or may be made of at least one of the n-type conductive material or the p-type conductive material. As a result, a carrier balance in the light-emitting layer 5 can be improved (for example, an injection ratio of holes can be increased). As illustrated in FIG. 5, at least a part or all of an outer peripheral portion 3 of the nanoparticle P may be made of the n-type conductive material (for example, an n-type semiconductor) or the p-type conductive material (for example, a p-type semiconductor). When at least a part or all of the outer peripheral portion 3 has p-type or n-type conductivity, the conductivity in that portion can be improved. A core 2 of the nanoparticle P may be an insulating material. The entirety of the outer peripheral portion 3 of the nanoparticle P may be made of the n-type conductive material (the core 2 may be coated with the n-type conductive material), or the entirety of the outer peripheral portion 3 of the nanoparticle P may be made of the p-type conductive material (the core 2 may be coated with the p-type conductive material).

Examples of the n-type conductive material include ZnO, ZnMgO, and an n-type chalcopyrite compound. Examples of the p-type conductive material include NiO doped with Ag and a p-type chalcopyrite compound.

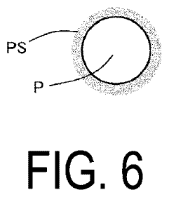

FIG. 6 is a cross-sectional view illustrating a configuration example of a periphery of the nanoparticle. As illustrated in FIG. 6, at least one of halogen or chalcogen may be included in a periphery PS of the nanoparticle P.

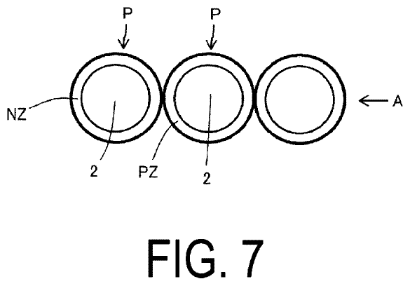

When the first nanoparticle group A1 and the like are collectively referred to as a nanoparticle group A, the nanoparticle group A may include the nanoparticle P including the n-type conductive material and another nanoparticle P including the p-type conductive material. FIG. 7 is a cross-sectional view illustrating a configuration example of a nanoparticle group. As illustrated in FIG. 7, the nanoparticle group A may include a nanoparticle P in which the core 2 is coated with an n-type conductive material NZ and another nanoparticle P in which the core 2 is coated with a p-type conductive material PZ.

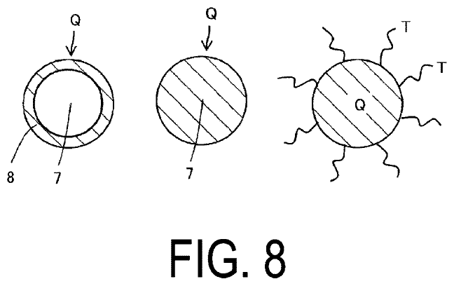

FIG. 8 is a cross-sectional view illustrating a configuration example of a quantum dot. When the first quantum dot Q1, the second quantum dot Q2, and the like are collectively referred to as a quantum dot Q, the quantum dot Q may be a core-shell type including a core 7 and a shell 8, or may be a shell-less type including only the core 7. A plurality of ligands T may be arranged on a periphery of the quantum dot Q. The ligand T may include at least one of halogen or chalcogen. Halogen is fluorine, chlorine, bromine and the like. When the distance between the quantum dots is small, the ligand is easily peeled off and the quantum dot is easily deactivated. However, by providing the nanoparticle between the quantum dots, a deactivation rate due to the peeling off of the ligand can be reduced. The ligand T may be made of an organic compound.

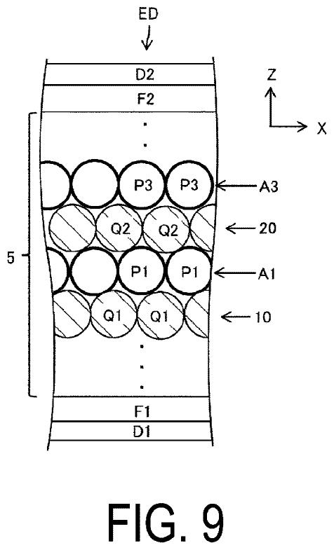

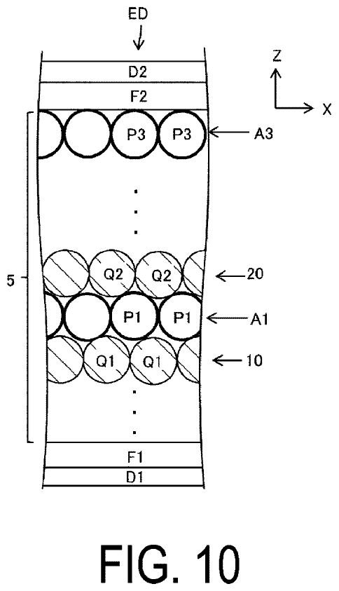

FIGS. 9 and 10 are cross-sectional views each illustrating a configuration example of the light-emitting element according to the present embodiment. As illustrated in FIGS. 9 and 10, the light-emitting layer 5 may include a third nanoparticle group A3 including the third nanoparticles P3 and spreading in a layered manner. In this case, as illustrated in FIG. 10, the third nanoparticle group A3 including a plurality of the third nanoparticles P3 may be located at an uppermost position (uppermost layer) of the light-emitting layer 5 and may be in contact with the charge function layer F2.

The first nanoparticle group A1 may have insulating properties, and the third nanoparticle group A3 may have n-type conductivity. In this case, the first electrode D1 may be an anode, and the second electrode D2 may be a cathode.

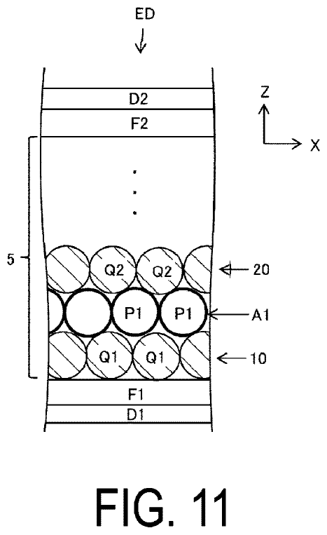

FIG. 11 is a cross-sectional view illustrating a configuration example of the light-emitting element according to the present embodiment. As illustrated in FIG. 11, the first quantum dot group 10 including a plurality of the first quantum dots Q1 may be located at a lowermost position (lowermost layer) of the light-emitting layer 5 and in contact with the charge function layer F1.

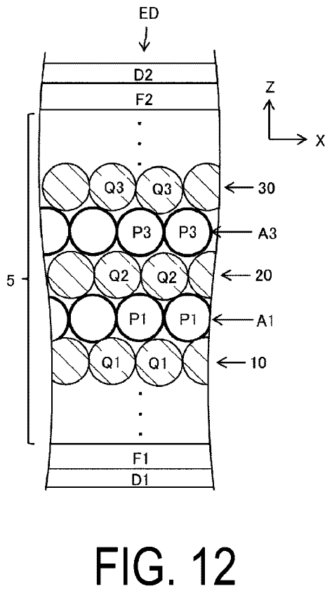

FIG. 12 is a cross-sectional view illustrating a configuration example of the light-emitting element according to the present embodiment. As illustrated in FIG. 12, the light-emitting layer 5 may include third quantum dots Q3 located between the second electrode D2 and the third nanoparticle group A3. The first quantum dot group 10, the first nanoparticle group A1, the second quantum dot group 20, the third nanoparticle group A3 including the plurality of third nanoparticles P3, and the third quantum dot group 30 including a plurality of the third quantum dots Q3 may be arranged in this order from the lower layer side. For example, in order to improve the carrier balance (improve the excess of electrons), the nanoparticle group (A1 when D1 is the anode, A3 when D2 is the anode) closer to the anode may have the p-type conductivity, and the nanoparticle group (A3 when D2 is the cathode, A1 when D2 is the anode) closer to the cathode may have insulating properties.

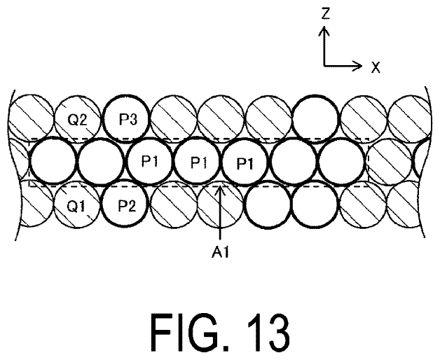

FIG. 13 is a cross-sectional view illustrating a configuration example of the light-emitting element according to the present embodiment. As illustrated in FIG. 13, the first nanoparticle group A1 is only required to spread in a layered manner, and the first nanoparticle group A1 (a layer formed of a plurality of the first nanoparticles P1 continuously adjacent to each other in the X direction) may be discontinuous in the cross-section.

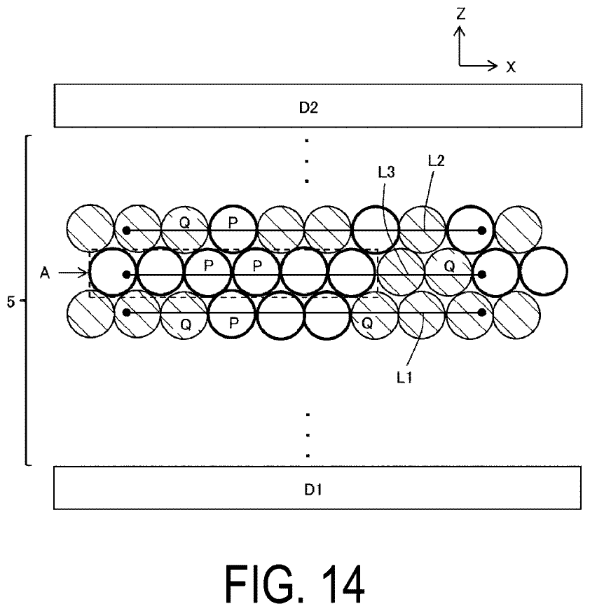

FIG. 14 is a cross-sectional view illustrating a configuration example of the light-emitting element according to the present embodiment. The light-emitting element illustrated in FIG. 14 includes the first and second electrodes D1 and D2, and the light-emitting layer 5 located between the first and second electrodes D1 and D2, and the light-emitting layer 5 includes a plurality of the quantum dots Q spreading in a layered manner. When a first line segment L1 is present with respect to the cross-section of the light-emitting layer 5 in the layer thickness direction (Z direction) in which the first line segment L1 extends in the first direction (X direction) orthogonal to the Z direction and passes through particles in which more than 50% are the quantum dots Q, it can be said that the plurality of quantum dots Q spread in a layered manner.

Similarly, the light-emitting layer 5 includes the plurality of quantum dots Q spreading in a layered manner. When a second line segment L2 is present in which the second line segment L2 is parallel to the first line segment L1 and is located closer to the second electrode D2 than the first line segment L1 and passes through particles in which more than 50% are the quantum dots Q, it can be said that the plurality of quantum dots Q spread in a layered manner. Similarly, the light-emitting layer 5 includes the plurality of the nanoparticles P spreading in a layered manner. When a third line segment L3 is present in which the third line segment L3 is parallel to the first line segment L1 and is located between the first line segment L1 and the second line segment L2 and passes through particles in which more than 50% are the nanoparticles P, it can be said that the plurality of nanoparticles P spread in a layered manner.

The first line segment L1, the second line segment L2, and the third line segment L3 have the same length (for example, the length of the 100 nm) and are aligned in the X direction. When the plurality of nanoparticles P spreading in a layered manner include at least the plurality of nanoparticles P continuously adjacent to each other in the X direction and more than 60%, or more than 70%, or more than 80%, or more than 90% of particles through which the L3 passes are the plurality of nanoparticles P, it can be said that the plurality of nanoparticles P spread in a layered manner. Similarly, when the plurality of quantum dots Q spreading in a layered manner include at least the plurality of quantum dots Q continuously adjacent to each other in the X direction and more than 60%, more than 70%, more than 80%, or more than 90% of particles through which the L1 or L2 passes are the plurality of nanoparticles P, it can be said that the plurality of quantum dots Q spread in a layered manner.

### Manufacturing Method for Light-Emitting Element

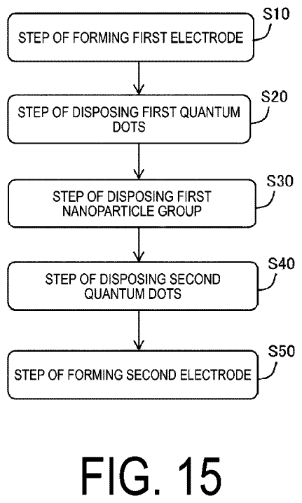

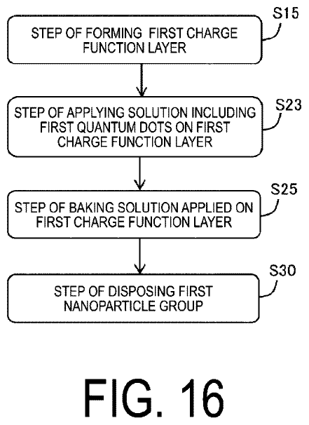

FIGS. 15 and 16 are flowcharts illustrating an example of the manufacturing method for the light-emitting element of the present embodiment. As illustrated in FIGS. 1 and 15, the manufacturing method for the light-emitting element of the present embodiment includes a step of forming the first electrode D1 (S10), a step of disposing the first quantum dots Q1 above the first electrode D1 (S20), a step of disposing the first nanoparticle group A1 including the first nanoparticles P1 and spreading in a layered manner above the first quantum dots Q1 (S30), a step of disposing the second quantum dots Q2 above the first nanoparticle group A1 (S40), and a step of forming the second electrode D2 above the second quantum dots Q2 (S50).

As illustrated in FIG. 16, after step S10 and step S30, a step of forming the first charge function layer F1 (S15), a step of applying a liquid including the first quantum dots Q1 on the first charge function layer F1 (at a position above the first electrode D1) (S23), and a step of baking the liquid applied on the first charge function layer F1 (S25) may be performed. In the case of manufacturing the light-emitting element ED as illustrated in FIGS. 3 and 4, in step S23, a liquid including the first quantum dots Q1 and the second nanoparticles P2 may be applied on the first charge function layer F1 (at a position above the first electrode D1).

### Example 1

The light-emitting element in FIG. 1 may be formed as follows. First, a first quantum dot liquid including the first quantum dots Q1, a first nanoparticle liquid including the first nanoparticles P1, and a second quantum dot liquid including the second quantum dots Q2 were prepared. The first and second quantum dots Q1 and Q2 have the same structure. The concentration of the first quantum dots Q1 in the first quantum dot liquid is 20 mg/ml, and a solvent of the first quantum dot liquid is octane. The first nanoparticle P1 in the first nanoparticle liquid is made of SiO₂, the concentration of the first nanoparticles P1 is 30 mg/ml, and a solvent of the first nanoparticle liquid is octane.

Next, the first quantum dot liquid was applied onto the first charge function layer F1 (for example, the hole transport layer) by a spin coating method. The rotational speed in the spin coating method was 3000 rpm/40 sec. An average thickness of the first quantum dot group A1 having a layered manner obtained after the baking of the first quantum dot liquid was about one time the diameter of the first quantum dot Q1.

Next, the first nanoparticle liquid was applied onto the first quantum dot group A1 by a spin coating method. The rotational speed in the spin coating method was 3500 rpm/40 sec. The average thickness of the obtained first nanoparticle group 10 was about one time the diameter of the first nanoparticle P1.

Next, the second quantum dot liquid was applied onto the first nanoparticle group 10 by a spin coating method. The rotational speed in the spin coating method was 3000 rpm/40 sec. An average thickness of the second quantum dot group 20 having a layered manner obtained after the baking of the second quantum dot liquid was about one time the diameter of the second quantum dot Q2.

### Example 2

The nanoparticles in FIG. 5 may be formed as follows. SiO₂ nanoparticles were prepared as the cores 2 of the nanoparticles P. Then zinc acetate dihydrate (Zn(CH₃COO)₂·2H₂O), ammonia (NH₃), and sodium dodecyl sulfate (SDS) were added to a mixed solvent of water (H₂O) and ethanol (EtOH) to obtain a mixed solution. Then, the SiO₂ nanoparticles were added to the mixed solution and stirred while heated to 75° C. As a result, zinc oxide (ZnO) was grown on SiO₂. As a result, the nanoparticles P each including the core 2 made of an insulating material and the outer peripheral portion 3 (shell) made of an n-type conductive material were obtained.

### Example 3

The nanoparticles in FIG. 5 may be formed as follows. SiO₂ nanoparticles were prepared as the core 2 of the nanoparticles P. Nickel acetate tetrahydrate was added to a mixed solvent of methoxyethanol and aminoethanol at a concentration of 0.1 mol/L to 0.4 mol/L to obtain a mixed solution. Then, the SiO₂ nanoparticles were added to the mixed solution and stirred while heated. As a result, nickel oxide (NiO) was grown on SiO₂. As a result, the nanoparticles P each including the core 2 made of an insulating material and the outer peripheral portion 3 (shell) made of an p-type conductive material were obtained.

### Display Device

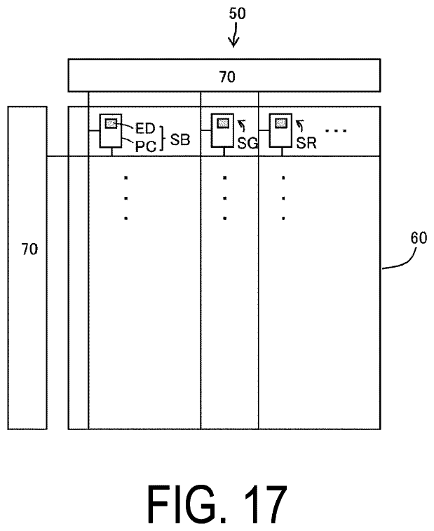

FIG. 17 is a schematic view illustrating a configuration example of a display device including the light-emitting element according to the present embodiment. As illustrated in FIG. 17, a display device 50 includes a display portion 60 including a plurality of subpixels SB, SG, and SR, and a driver 70 for driving the plurality of subpixels SB, SG, and SR. For example, the subpixel SB includes the light-emitting element ED and a pixel circuit PC connected to the light-emitting element ED. The subpixel SB may be a blue subpixel including the light-emitting element ED emitting blue light. The subpixel SG may be a green subpixel and the subpixel SR may be a red subpixel.

### APPENDIX

The embodiments described above are for the purpose of illustration and description and are not intended to be limiting. It will be apparent to those skilled in the art that many variations will be possible in accordance with these examples and descriptions.

1. A light-emitting element comprising:
a first electrode;
a second electrode; and
a light-emitting layer located between the first electrode and the second electrode,
wherein the light-emitting layer includes
a first nanoparticle group including first nanoparticles and spreading in a layered manner,
a first quantum dot located between the first electrode and the first nanoparticle group and differing from each of the first nanoparticles in at least one of a constituent element, a composition, or a particle diameter, and
a second quantum dot located between the second electrode and the first nanoparticle group and differing from each of the first nanoparticles in at least one of a constituent element, a composition, or a particle diameter.

2. The light-emitting element according to claim 1,
wherein each of the first nanoparticles includes an insulating material.

3. The light-emitting element according to claim 1,
wherein the first quantum dot and the second quantum dot have at least one of equivalence in particle diameter, identity in constituent element, or identity in luminance color.

4. The light-emitting element according to claim 1,
wherein a particle diameter of each of the first nanoparticles is equivalent to a particle diameter of the first quantum dot.

5. The light-emitting element according to claim 1,
wherein a particle diameter of each of the first nanoparticles is smaller than a particle diameter of the first quantum dot.

6. The light-emitting element according to claim 1,
wherein a band gap of each of the first nanoparticles is greater than a band gap of the first quantum dot.

7. The light-emitting element according to claim 1,
wherein each of the first nanoparticles includes at least one of an n-type conductive material or a p-type conductive material, and
the first nanoparticle group includes the first nanoparticle including the n-type conductive material and another first nanoparticle including the p-type conductive material.

8.-10. (canceled)

11. The light-emitting element according to claim 87,
wherein the first nanoparticle group includes the first nanoparticle coated with the n-type conductive material and the other first nanoparticle coated with the p-type conductive material.

12.-14. (canceled)

15. The light-emitting element according to claim 1,
wherein the light-emitting layer includes a second nanoparticle located between the first electrode and the first nanoparticle group.

16. The light-emitting element according to claim 15,
wherein the second nanoparticle and the first quantum dot are adjacent to each other in a direction orthogonal to a layer thickness direction of the light-emitting layer.

17. The light-emitting element according to claim 15- or 16,
wherein the second nanoparticle is a semiconductor crystal having a band gap greater than a band gap of the first quantum dot.

18. The light-emitting element according to claim 15,
wherein a particle diameter of the second nanoparticle is smaller than a particle diameter of the first quantum dot.

19. The light-emitting element according to claim 1,
wherein the light-emitting layer includes a third nanoparticle located between the second electrode and the first nanoparticle group.

20. The light-emitting element according to claim 19,
wherein the third nanoparticle and the second quantum dot are adjacent to each other in a direction orthogonal to a layer thickness direction of the light-emitting layer.

21. The light-emitting element according to claim 19,
wherein the third nanoparticle is a semiconductor crystal having a band gap greater than a band gap of the second quantum dot.

22. The light-emitting element according to claim 19,
wherein the light-emitting layer includes a third nanoparticle group including a plurality of the third nanoparticles and spreading in a layered manner.

23. The light-emitting element according to claim 22,
wherein the third nanoparticle group is located at an uppermost position in the light-emitting layer.

24. The light-emitting element according to claim 22,
wherein the first nanoparticle group has insulating properties, and
the third nanoparticle group has n-type conductivity.

25. The light-emitting element according to claim 22,
wherein the light-emitting layer includes a third quantum dot located between the second electrode and the third nanoparticle group.

26.-27. (canceled)

28. A display device comprising:
the light-emitting element according to claim 1.

29.-31. (canceled)
